(19) United States
(12) Patent Application Publication
(10) Pub. No.: US 2017/0279028 A1
(43) Pub. Date: Sep. 28, 2017

(54) PURPOSING AND REPURPOSING A GROUP OF COMPOUNDS THAT CAN BE USED AS HIGH TEMPERATURE SUPERCONDUCTORS

(71) Applicants: Dong Zhao, Cleveland, OH (US); George Jin Zhao, Cleveland, OH (US)

(72) Inventors: Dong Zhao, Cleveland, OH (US); George Jin Zhao, Cleveland, OH (US)

(73) Assignee: Eastern Plus, LLC, Cleveland, OH (US)

(21) Appl. No.: 15/077,683

(22) Filed: Mar. 22, 2016

(51) Int. Cl. H01L 39/12; C01F 15/00

(52) U.S. Cl. CPC H01L 39/12; C01F 15/00; C01P 2006/40

(57) ABSTRACT

This disclosure will describe a novel finding and make the claim for the first time on a group of old compounds and formulated new compounds. These compounds have superconducting property at high temperatures, i.e., 151K or higher. Several compounds were prepared, though not well-purified, at around middle of 1900s. Their chemical, structural, electric and magnetic properties were studied and reported but their superconducting property has not been known and has never been exploited because the idea of type-II superconductivity was not proposed at that time. Consequently, we claim this finding as an invention even though our invention is based on the studies of the compounds' electric and magnetic properties along with their crystallographic features from the previous publications. The experiments to further verify their high temperature superconductivity require the utilization of sophisticated facilities on synthesizing highly pure compounds and the deregulation from government security authorities on purchasing the starting materials.

### TECHNICAL FIELD

The present invention provides a group of compounds that have the electric superconducting property at 151K or higher that, we believe, have the potential to reach a superconducting transition (critical) temperature (Tc) of the room temperature or even higher. Here, the 151K is the temperature defined as the low end of the Tc for the superconductors of this disclosure because no stable superconductor reported hitherto has its Tc reached this mark at ambient conditions. In other words, the high temperature superconducting states for these materials or compounds neither require being obtained by energy boosting through, but not limited to, external radiation, nor exist transiently for only a short period of time. Also, the high temperature superconducting states exist at atmosphere pressure, meaning they do not require applying additional external pressures.

The chemical formulae or the compositions of the compounds can be written as (M)(X)n, where the M is at least one from the actinide elements, i.e., actinium (Ac), thorium (Th), protactinium (Pa), uranium (U), Neptunium (Np), plutonium (Pu), americium (Am), curium (Cm), berkelium (Bk), californium (Cf), einsteinium (Es), fermium (Fm), mendelevium (Md), nobelium (No), lawrencium (Lr), and their isotopes; the X represents at least one element from fluorine (F), chlorine (Cl), bromine (Br), iodine (I), astatine (At), oxygen (0), sulfur (S), selenium (Se), tellurium (Te), nitrogen (N), phosphorus (P), arsenic (As), antimony (Sb), carbon (C), silicon (Si), germanium (Ge), boron (B) and their isotopes; the n is a value ranging from 0.05 to 20.

Because of the chemical resemblance between groups of actinide and lanthanide (rare earth), the elements from the lanthanide group are also included in this invention and hence the M, hereinbefore, also encompasses lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu) and their isotopes.

In a separate effort on widening the search for the high temperature superconductors, a couple of compounds made by early transition metals were also found. This is because several of these transition metal compounds demonstrated the similar electromagnetic properties of the actinide salts. The properties of these transition metal compounds are very sensitive to their chemical stoichiometry. For instance, TaC_{0.8} (n=0.8) and NbC_{0.8} (n=0.8) both exhibited coexistence of electric conductivity and diamagnetism at room temperature while their property of diamagnetism changes dramatically with slight change of the n values. Therefore these transition elements are assigned to the M for the above formulae of (M)(X)n as the candidates to build the high Tc superconductors of this invention. These transition metals are, scandium (Sc), titanium (Ti), vanadium (V), chromium (Cr), manganese (Mn), yttrium (Y), zirconium (Zr), niobium (Nb), molybdenum (Mo), technetium (Tc), hafnium (Hf), tantalum (Ta) tungsten (W), rhenium (Re) and their isotopes.

Among the aforementioned compounds composed according to the formulae of (M)(X)n, several of them were made in the past but their superconducting property has not been realized hitherto. Consequently, this invention is to repurpose these known compounds, for the first time, as the high temperature superconducting materials. The rest of the compounds, again formulated by (M)(X)n, are new and have never been synthesized heretofore. The second part of this invention is to purpose these new formulated compounds as the candidates of the high temperature superconductors. Again, these new formulated compounds fit the aforementioned formulae of (M)(X)n with the elements for the M and the X defined above as well as the n ranging from 0.05 to 20.

### BACKGROUND

Since the first discovery of the superconductive phenomenon of mercury at its Tc of 4.2 k in 1911, the work of exploring higher and higher Tc superconductors progressed slowly for about 75 years. This slow progress was interjected by the major revolutionary discovery of superconductivity on certain lanthanum based cuprate Perovskite ceramics, the so called type II superconducting materials, in 1986. This finding leaded the Tc to successfully outreach the milestone of 77 k, i.e., the boiling temperature of liquid nitrogen, at the same year. The further enhancement of Tc on the cuprate Perovskite ceramics via cation and/or anion modifications reached in the vicinity of 138 K in 1995, which is the widely accepted highest world record of Tc hitherto.

It has been almost 30 years after the discovery of the type II superconductivity. Great effort on preparing higher and higher Tc superconductive materials has been made in the hope of exceeding the other two major milestones, viz., the melting point of water (273 K) and the room temperature (298 K). Even though, the studies on certain cuprate Perovskites via an external optic stimulation showed possible room temperature superconductivity, but the results will need to be reconfirmed by different experiments while the reported metastable superconducting state existed too short in a span of several nanoseconds to be used in any application. Theoretically speaking, this super short life time of superconducting state would make other experiments to confirm its existence extremely difficult.

It is of great importance to have a stable superconducting material whose Tc can surpass one or both of the hereinbefore 273 K and 298 K milestones. Technically speaking, the even stricter requirements than the abovementioned two temperature marks of 273K and 298K for low power application needs the Tc of superconductor to top 350K while Tc for high power application should outpace 450K. A tremendous amount of effort has been made, aiming to accomplish these tasks. Unfortunately, most works have not come close to the milestones while the others that claimed to have room temperature superconductivity were neither confirmed nor accepted by other professionals.

### DISCLOSURE OF INVENTION

Our approach to accomplish the task of obtaining the high temperature superconductors started with conducting the literature search/research on the previous superconducting materials. We found that the superconducting salts prepared hitherto hardly contain the element(s) from the actinide group. Our subsequent searches on the actinide compounds in the literatures along with our analyses of the compounds' properties and their structural features guided us this invention.

The embodiment of this invention is to exemplify a couple of thorium (Th) salts even though it is not intended to limit the scope of this invention to only the Th compounds.

The majority of the conductive thorium salts were synthesized at around the 1960s. Besides their high electrically conductive feature under room temperature and atmosphere pressure, one of their inimitable properties is their diamagnetic behavior, also at ambient conditions. Notice that this co-existence of electrically conductive and diamagnetic properties is unique to superconductors while normal conductors do not possess these characteristics.

The aforementioned unique feature of the co-existence of both electrically conductive and diamagnetic properties under ambient conditions, i.e., the conditions that the compounds being characterized, hinted us that this group of compounds should have reached their superconducting states at least at room temperature. In other words, these thorium compounds have achieved their superconducting states at room temperature and under atmospheric pressure because of their unique property of co-existence of high electric conductivity and diamagnetism at ambient conditions. Further exploration on how high and/or how low the temperatures, at which the thorium compounds fall into their superconducting states, will need to carry out a completely new round of studies beginning from the syntheses toward high purity of the relative compounds.

Investigations on the structural features of the thorium compounds were also performed. Their X-ray crystallographic results were analyzed, especially for thorium di-iodide (ThI₂) and thorium mono-sulfide (ThS).

ThI₂ crystallized in space group P6₃/mmc in hexagonal lattice with a-axis of 0.397 nm and an exceptional long c-axis of 3.175 nm. The reason for the long c-axis is because each Th cation is surrounded by 6 I anions in two geometries, i.e., trigonal-antiprismatic (anti-Pris) and trigonal-prismatic (Pris) arrangements. Each hexagonal cell consists of four layers of them along c-axis packed in an alternating manner, i.e., anti-Pris/Pris/anti-Pris/Pris. Each individual trigonal-prismatic or trigonal-antiprismatic of their pairs in a crystallographic unit cell is located at different cell positions and different orientations on their (0001) planes, i.e., atoms of trigonal-prismatic (or trigonal-antiprismatic) having different x and y values relative to another trigonal-prismatic (or trigonal-antiprismatic) of their pairs in the lattice. We re-plotted its unit cell and its individual [ThI₆] structures layer by layer, and we also expanded the plotting of each layer into 4 unit cells. The 4-cell plotting exhibited the planar structure through joining the common edges of either trigonal-antiprismatic or trigonal-prismatic [ThI₆] structural units to construct the two dimensional layered linkage running on the planes parallel to the c-axis. The structural feature of this layered edge sharing connections has also been observed in the crystallographic packing style of other superconductors. This means compound ThI₂ meets the structural criterion for being a superconducting material.

ThS has similar electromagnetic properties as ThI₂ but its crystal structure is cubic, same as the packing of sodium chloride (NaCl), with a=0.568 nm. Its crystallographic structure also revealed the two dimensional layered linkage along <110> directions with edge-sharing characters assembled by the structural units of the [ThS₆] octahedra. The character of this crystallographic layered packing for the ThS compound, again, qualifies the structural demand as a superconductor.

Instead of iodide and sulfide, the co-existence of electric conductivity and diamagnetism associated with actinide compounds, especially for thorium compounds, at relatively high temperature may also be found for their carbide, nitride, boride, etc., as well as their combinations, such as carbonitride. These compounds can also become the candidates for the high temperature superconducting materials of this invention.

It is reported that ThC_{0.78}N_{0.22} is a superconductor but its Tc is too low at about 5.8 K. This compound does not have the property of co-existence of both electric conductivity and diamagnetism at 151K or higher. Therefore, this compound cannot become the candidate for this invention, even though its molecular formula falls into the (M)(X)n compositions as remarked in this disclosure. In other words, only these compounds that fit the formulae of (M)(X)n described hereinbefore and have their Tc of 151K or higher belong to the superconductors of this invention. Moreover, compound ThC_{0.78}N_{0.22} fits the formulae of (M)(X)n in a way that M=Th, X═C_{n-0.22}N_{n-0.78}, viz, the binary anion, and n=1.

### ROUTES OF SYNTHESES OF THE HIGH TEMPERATURE SUPERCONDUCTORS

The previous synthetic work of the conductive Th compounds in the 1960s ended up with about 5% impurities by weight. The majority of the impurities were confirmed non-stoichiometric species and Th oxides. This means the new synthetic pathways may require the use of more sophisticated facilities and probably through new reaction procedures. The reasons for these changes are on the purpose of well controlling the stoichiometry of the syntheses as well as avoiding the oxidation and/or contamination by oxygen and water under the high synthetic temperatures, i.e., up to 2200° C., with or without employing vacuum or inert atmosphere techniques in order to really obtain the pure compounds. These harsh requirements may impose difficulties on the new synthetic processes while the reaction methods and procedures may need to be modified and optimized over time. The examples of synthetic routes, hereinafter, are only used to exemplify the ideal situation that the superconducting materials can be made stoichiometrically without oxygen or water oxidation. The further exploration on optimizing the synthetic methods for preparing the high purity of the high temperature superconducting compounds is beyond the scope of this invention.

High temperature solid state reaction can be utilized for this invention. Thorium as one of the most studied elements in the actinide group will be described here while ThS will be exploited as the example in this disclosure.

Albeit many methods of synthesizing thorium sulfide were reported, only three major preparative routes for ThS were utilized here to show the basic ways on making this compound, i.e., two-step synthesis, one-step method and metal hydride technique.

### EXAMPLE 1

### Two-Step Route

The two-step synthetic route requires the first preparation of thorium di-sulfide (ThS₂) as the starting material for the second step.

ThS₂ can be made by reacting Th metal with excess amount of hydrogen sulfide (H₂S) under vacuum at around 1200-1500° C. The duration of the reaction was not reported but the chemical reaction was claimed to be very fast for the finely thorium metal particles.

ThS can thus be synthesized by mixing the stoichiometric amount of ThS₂ and Th metal, and then heating to 2000-2200° C. under vacuum.

### EXAMPLE 2

### One-Step Route

Heating the mixture of thorium metal and proper amount of H₂S to about 2000° C. under reduced pressure could produce ThS.

One-step route is relatively simple but the control of the stoichiometry of the reactants to produce the pure ThS may be challenging.

### EXAMPLE 3

### Thorium Hydride as Starting Material

The reaction to form thorium hydride (ThH₂) proceeds relatively easy depending on the temperature. For converting 300 grams of thorium metal into thorium hydride, the duration is about 10 hours at 300° C. But the time duration can be reduced to only a few minutes if the temperature is increased to 400-500° C. initially and then decreased to 300° C. after the reaction starts.

Thorium hydride is then allowed to react with stoichiometric amount of hydrogen sulfide (H₂S) at around 400-500° C. to generate ThS.

### BRIEF DESCRIPTION OF DRAWINGS

FIG. 1 displays the history of superconductor development by plotting the advances of the superconducting transition (critical) temperature, Tc, in Kelvin (K) against the time in year.

FIG. 2A and FIG. 2B exhibit two geometries for the [ThI₆] structural units: (A) Trigonal-antiprismatic (anti-Pris), and (B) Trigonal-prismatic (Pris).

FIG. 3 highlights the crystallographic unit cell of ThI₂ in a way that two geometries of the [ThI₆] units, i.e., anti-Pris and Pris, are stacked alternatively along c-axis.

FIG. 4A-4D illustrate the orientations of the atomic geometries for each individual layers along the crystallographic c-axis of the ThI₂ hexagonal unit cell as shown in FIG. 3, where the positions (x, y, z) of thorium (Th) cations are (A) (⅔,⅓,¾); (B) (0, 0, ½); (C) (⅓,⅔,¼); and (D) (0, 0, 0).

FIG. 5A-5D expand the connections of each layer in FIG. 4A-4D into four unit cells relatively and reveal the layered edge-sharing property of ThI₂. The connections in FIG. 5A and FIG. 5C are easy to see and only the side views are given while the extra top views in FIG. 5B and FIG. 5D are included for better visualizing the edge-sharing features of the 4-cell connections of the four [ThI₆] units.

FIG. 6 gives a layout of a typical ThS (NaCl structure) and its layer feature on {111} planes is demonstrated, i.e., the thorium cations (Th) and sulfur anions (S) are packed alternatively.

FIG. 7A reveals the crystal structure of ThS, where the six solid balls, representing sulfur anions (S), are replace by hollow ones, also representing sulfurs, in order to depict the octahedral enclosure of sulfur anions (S) around one thorium cation (Th).

FIG. 7B is an individual [ThS₆] octahedral structural unit stripped from FIG. 7A.

FIG. 8 delineates the geometric arrangement of the ThS with the edge-sharing octahedral units of [ThS₆].

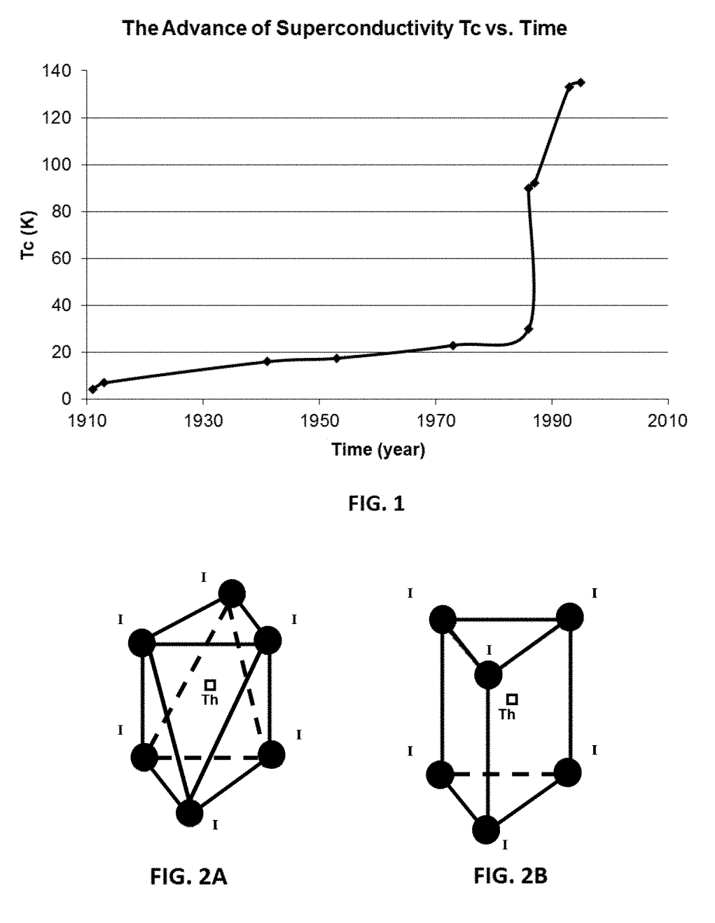

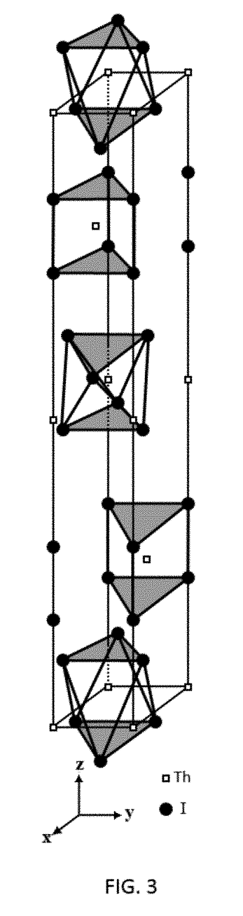

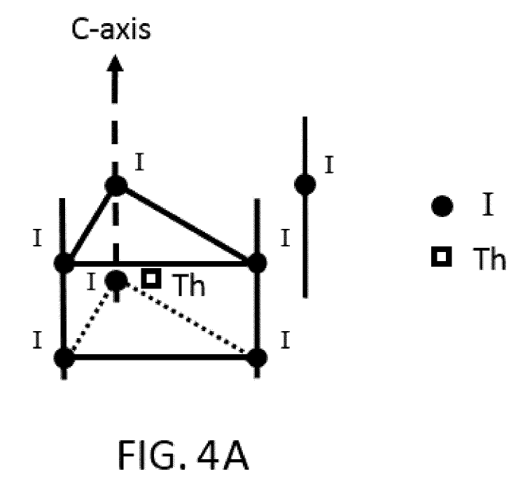

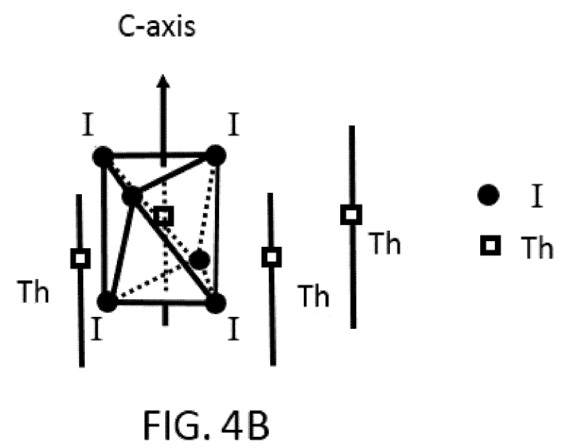

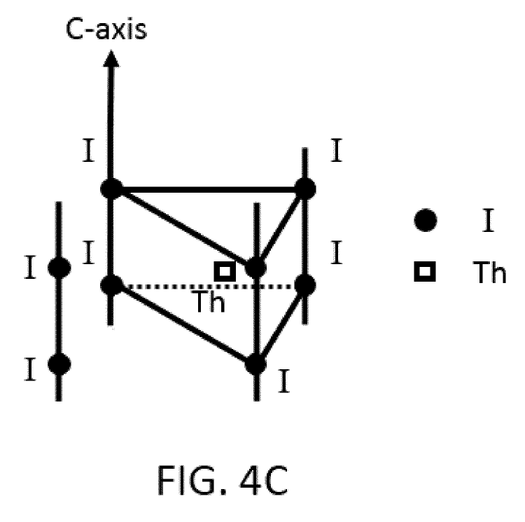

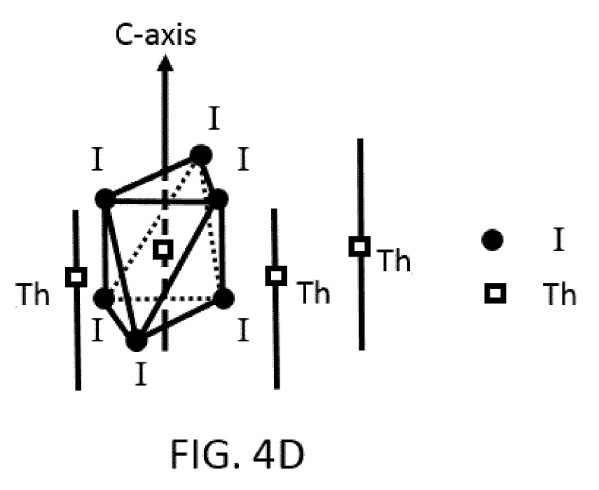

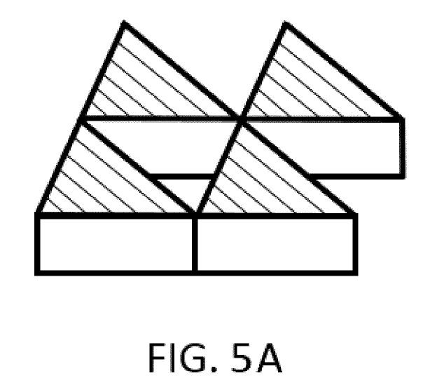

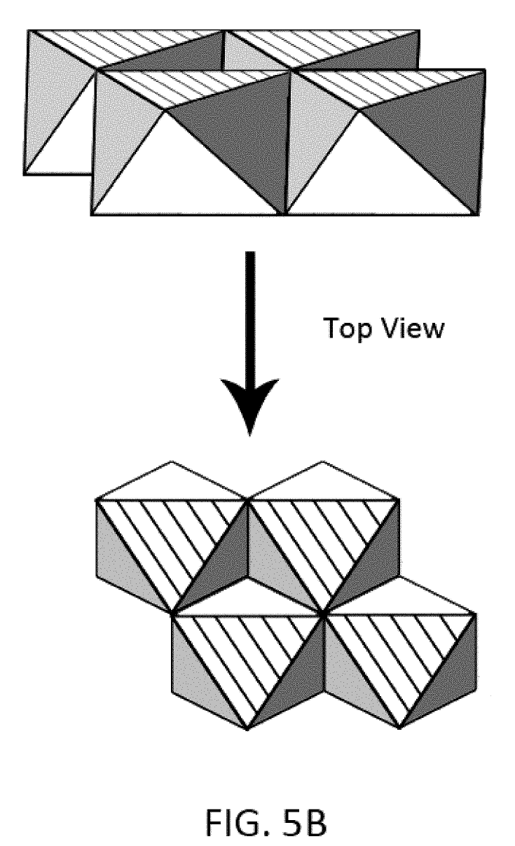

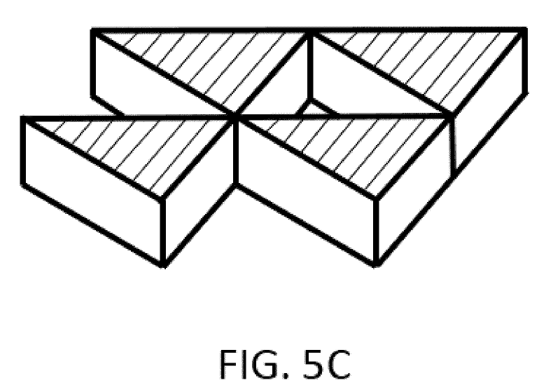

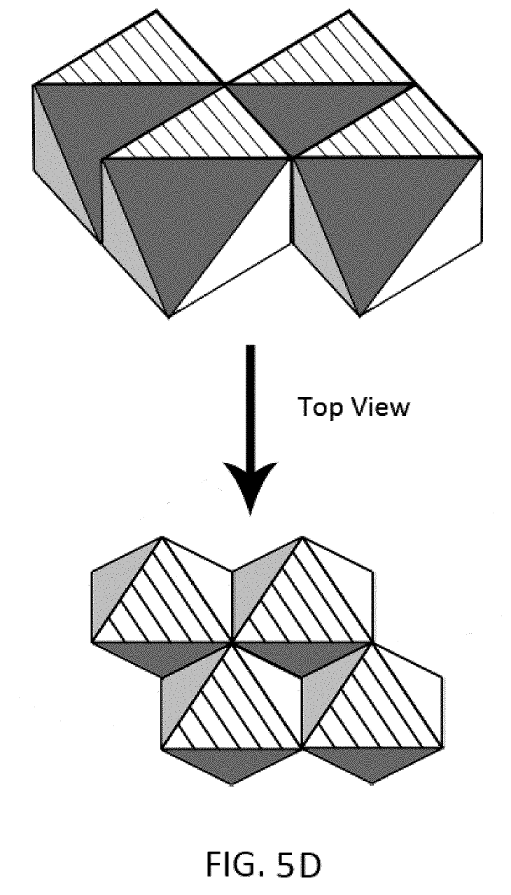

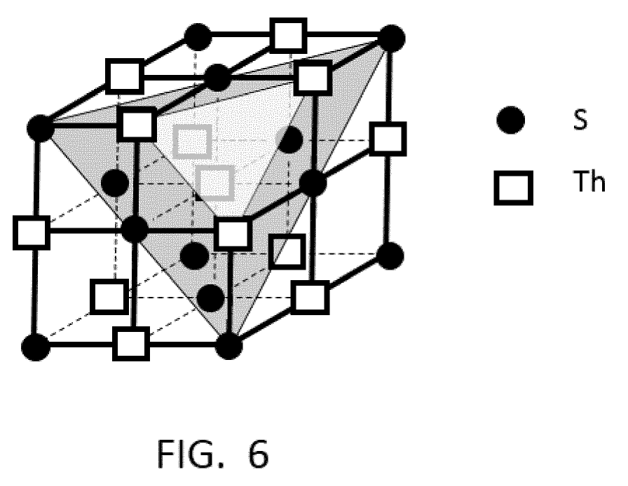

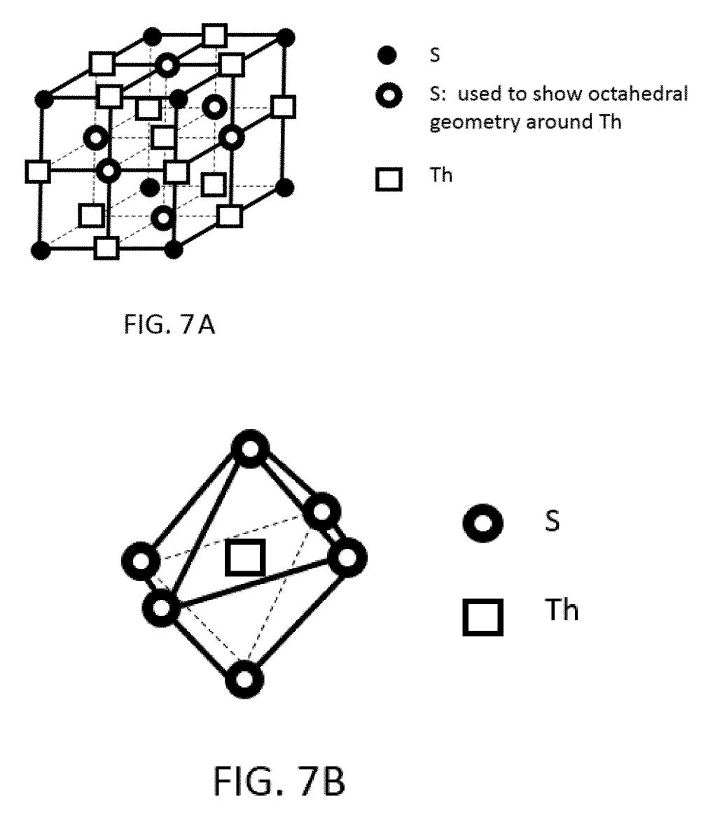

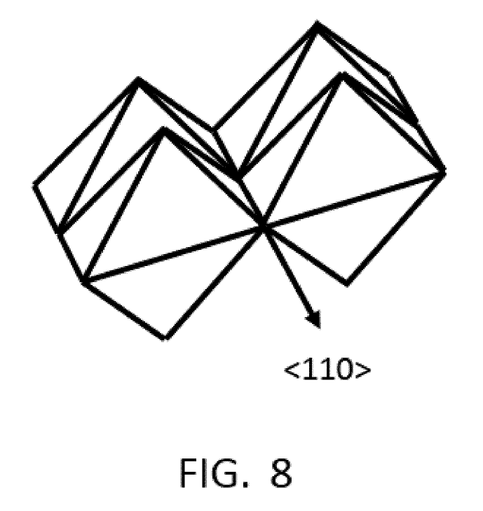

What the invention claims is:

1. A group of electrical superconducting materials or compounds with their chemical formulae or compositions written as (M)(X)n, where the M is at least one from the actinide, lanthanide and early transition elements, i.e., actinium (Ac), thorium (Th), protactinium (Pa), uranium (U), Neptunium (Np), plutonium (Pu), americium (Am), curium (Cm), berkelium (Bk), californium (Cf), einsteinium (Es), fermium (Fm), mendelevium (Md), nobelium (No), lawrencium (Lr), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), scandium (Sc), titanium (Ti), vanadium (V), chromium (Cr), manganese (Mn), yttrium (Y), zirconium (Zr), niobium (Nb), molybdenum (Mo), technetium (Tc), hafnium (Hf), tantalum (Ta) tungsten (W), rhenium (Re) and their isotopes; the X represents at least one element from fluorine (F), chlorine (Cl), bromine (Br), iodine (I), astatine (At), oxygen (0), sulfur (S), selenium (Se), tellurium (Te), nitrogen (N), phosphorus (P), arsenic (As), antimony (Sb), carbon (C), silicon (Si), germanium (Ge), boron (B) and their isotopes; and the n is a value ranging from 0.05 to 20;

2. The M and the X for formulae (M)(X)n in claim 1 also contain multiple numbers and/or multiple types of cations (actinide and/or lanthanide and/or early transition metals) and/or multiple numbers and/or multiple types of anions (non-metal), meaning the M in above formulae can also represent the combination of two or more elements and/or numbers from actinide group and/or lanthanide group and/or early transition group listed above in claim 1 while the X can include multiple numbers and/or multiple types anions from the above elemental candidates also in claim 1;

3. The criteria for the materials or the compounds in claim 1 to become a high temperature superconductor for this invention are, firstly, the compounds must match the chemical formulae of (M)(X)n defined in claim 1 with the elements for the M and the X listed in claim 1 to build them using the appropriate n values in the range of 0.05 to 20, and secondly, the compounds must own the property of the co-existence of the electric conductivity and the diamagnetism at 151K or higher, i.e., having superconducting Tc of at least 151K (inclusive), where no stable superconductor that possesses the Tc at atmosphere pressure has been reported to reach this temperature mark heretofore. This means the low temperature end of the superconductors' Tc in this invention is still higher than the highest Tc of current known superconductors while the high temperature end of the superconductors' Tc in this invention has the potential to surpass all the aforementioned milestones;

4. The Tc temperature range for the superconductors in claim 1 can go higher than 151K, meaning the Tc range of this invention is from 151K up to the temperature of the highest Tc of the compound(s) in claim 1. At least the Tc of room temperature was evidenced by the compounds of, but no limited to, ThI₂, ThS, TaC₈, NbC_{0.8}, Ti(C)n, Zr(C)n, Hf(C)n and probably V(C)n. Therefore, there should be great potential for those compounds and/or their modifications and/or other compounds defined in claim 1 to have the Tc to surpass the room temperature or even the 450K milestones;

5. Even though, the materials or compounds in claim 1 normally have layered molecular configuration connected through repeating structural units or coordination polyhedrons centered by metallic atoms, but this invention has no intention to limit the molecular configuration to only the two dimensional layered type and thus layered linkage is not a criterion for the compounds being the candidate of this disclosure;

6. The superconductors described in claim 1 can be, but not limited, in single crystal, polycrystalline or amorphous, or in bulk, thin film or single molecular layer;

7. The superconductors described in claim 1 should be stable at ambient conditions, meaning there is no need to apply external energy, such as but no limited to, radiation and/or no need to apply external pressure to reach their superconducting states as long as the temperature is below its/their Tc(s).
